(19) United States
(12) Patent Application Publication
(10) Pub. No.: US 2023/0253697 A1
(43) Pub. Date: Aug. 10, 2023

(54) DISPLAY SUBSTRATE, DISPLAY PANEL AND DISPLAY DEVICE

(71) Applicants: Beijing BOE Optoelectronics Technology Co., Ltd., Beijing (CN); BOE Technology Group Co., Ltd., Beijing (CN)

(72) Inventors: Xian WANG, Beijing (CN); Yu ZHAO, Beijing (CN); Dawei FENG, Beijing (CN); Hailong WANG, Beijing (CN); Huairui YUE, Beijing (CN); Yang GE, Beijing (CN); Jianwei MA, Beijing (CN); Yong ZHANG, Beijing (CN); Jian WANG, Beijing (CN); Hao YAN, Beijing (CN); Feng QU, Beijing (CN)

(21) Appl. No.: 17/785,712

(22) PCT Filed: Sep. 9, 2021
(86) PCT No.: PCT/CN2021/117370

§ 371 Date: Jun. 15, 2022

(30) Foreign Application Priority Data
Oct. 29, 2020 (CN) 202011186764.6

(51) Int. Cl. H01Q 1/22; G02F 1/1362; H01L 27/12; H01Q 1/38

(52) U.S. Cl. CPC H01Q 1/22; G02F 1/136286; H01L 27/124; H01L 27/1255; H01Q 1/38; G02F 1/133512

(57) ABSTRACT

Disclosed are a display substrate, a display panel and a display device. The display substrate has a display region and a non-display region, wherein the display substrate includes a base substrate; a near-field communication antenna on the base substrate and comprising a main body, wherein the main body is in the display region, and at least a portion of the main body is transparent.

### TECHNICAL FIELD

The present disclosure relates to the field of display technology, in particular to a display substrate, a display panel and a display device.

### BACKGROUND

Near-field Communication (NFC) technology is widely applied to the fields of mobile payment, electronic tickets, door access, anti-counterfeiting, and the like due to its advantages such as low cost, high bandwidth, high response speed, good security, and the like.

### SUMMARY

The present disclosure provides a display substrate, a display panel and a display device.

The present disclosure provides a display substrate having a display region and a non-display region. The display substrate includes a base substrate; and a near-field communication antenna on the base substrate and comprising a main body, wherein the main body is in the display region, and at least a portion of the main body is transparent.

In some embodiments, the body portion includes a metal mesh structure.

In some embodiments, the display substrate further includes a plurality of signal lines on the base substrate, wherein the plurality of signal lines are in the display region and insulated and spaced apart from the near-field communication antenna, and the metal mesh structure includes a first metal line and a second metal line intersected with each other.

In some embodiments, the plurality of signal lines include a plurality of gate lines in a gate metal layer and a plurality of data lines in a source-drain metal layer, and the plurality of gate lines and the plurality of data lines intersect with each other and are spaced apart from each other by a first insulation layer. The first metal line is in the gate metal layer, and the second metal line is in the source-drain metal layer. The first metal line and the second metal line are connected to each other through a through-hole at a position where the first metal line intersects with the second metal line, and at least one of the first metal line and the second metal line is in the same layer as the plurality of gate lines or the plurality of data lines.

In some embodiments, the display substrate further includes a plurality of signal lines on the base substrate, the plurality of signal lines being in the display region and insulated and spaced apart from the near-field communication antenna. The metal mesh structure includes a plurality of metal lines, and an orthographic projection of at least one of the plurality of metal lines on the base substrate is within an orthographic projection of a corresponding signal line on the base substrate.

In some embodiments, an orthographic projection of each of the plurality of metal lines on the base substrate is within an orthographic projection of a corresponding signal line on the base substrate.

In some embodiments, the metal mesh structure includes a plurality of first metal lines and a plurality of second metal lines intersected with each other. The plurality of signal lines include a plurality of gate lines and a plurality of data lines intersected with each other and insulated and spaced apart from each other, and an orthographic projection of each of the plurality of first metal lines on the base substrate is within an orthographic projection of a corresponding gate line on the base substrate, and an orthographic projection of each of the plurality of second metal lines on the base substrate is within an orthographic projection of a corresponding data line on the base substrate.

In some embodiments, the plurality of first metal lines and the plurality of second metal lines are in a same layer, and the plurality of signal lines are on a side of the metal mesh structure away from the base substrate.

In some embodiments, the near-field communication antenna further includes a connection line in the non-display region, wherein the connection line and the main body are connected to each other to form an antenna coil, and two terminals of the antenna coil are connected to a control circuit.

In some embodiments, the near-field communication antenna further includes a first leading-out terminal and a second leading-out terminal respectively connected to first and second terminals of the antenna coil, wherein the first leading-out terminal, the second leading-out terminal and the connection line are in a same layer, and the non-display region is further formed with a bridge therein, an orthographic projection of the connection line on the base substrate passes through and intersects with an orthographic projection of the bridge on the base substrate, a second insulation layer is between a layer where the bridge is located and a layer where the connection line is located, the second leading-out terminal is connected to one terminal of the bridge through a through-hole in the second insulation layer, and the other terminal of the bridge is connected to the control circuit.

An embodiment of the present disclosure provides a display panel including above display substrate.

In some embodiments, the main body includes a metal mesh structure, the display panel further includes a counter substrate, a black matrix is disposed on the counter substrate, and an orthographic projection of metal lines of the metal mesh structure on the base substrate is within an orthographic projection of the black matrix on the base substrate.

An embodiment of the present disclosure provides a display device including above and a control circuit connected to the near-field communication antenna.

### BRIEF DESCRIPTION OF DRAWINGS

The accompanying drawings, which are provided for further understanding of the present disclosure and constitute a part of this specification, are for explaining the present disclosure together with the following exemplary embodiments, but are not intended to limit the present disclosure. In the drawings:

FIG. 1 is a schematic diagram showing a display substrate in some embodiments of the present disclosure.

FIG. 2 is an enlarged view of a local region Q in FIG. 1.

FIG. 3 is a schematic diagram showing wiring in a local region of a display substrate in some embodiments of the present disclosure.

FIG. 4 is a cross-sectional view taken along a line A-A′ of FIG. 3.

FIG. 5 is a cross-sectional view of a display panel in some embodiments of the present disclosure.

FIG. 6 is a schematic diagram showing a portion of a display substrate in other embodiments of the present disclosure.

FIG. 7 is a cross-sectional view taken along a line B-B′ of FIG. 6.

FIG. 8 is a cross-sectional view taken along a line I-I′ of FIG. 1 in some embodiments of the present disclosure.

FIG. 9 is a cross-sectional view taken along a line I-I′ of FIG. 1 provided in other embodiments of the present disclosure.

FIG. 10 is a diagram showing matching of resonance points for a near-field communication antenna in an embodiment of the present disclosure.

### DETAIL DESCRIPTION OF EMBODIMENTS

The specific embodiments of the present disclosure will be described in detail below with reference to the accompanying drawings. It should be understood that the specific embodiments described herein are only used to illustrate and explain the present disclosure, but not to limit the present disclosure.

In order to make the purpose, technical solutions and advantages of the embodiments of the present disclosure more clear, the technical solutions of the embodiments of the present disclosure will be clearly and completely described below with reference to the accompanying drawings of the embodiments of the present disclosure. Obviously, the described embodiments are some, but not all, embodiments of the present disclosure. Based on the described embodiments of the present disclosure, all other embodiments obtained by those of ordinary skill in the art without creative efforts fall within the protection scope of the present disclosure.

The terminology used herein to describe embodiments of the present disclosure is not intended to limit and/or define the scope of the present disclosure. For example, unless otherwise defined, technical or scientific terms used in this disclosure should have the ordinary meaning as understood by one of ordinary skill in the art to which this disclosure belongs. It should be understood that the use of “first,” “second,” and similar terms in the present disclosure do not denote any order, quantity, or importance, but are merely used to distinguish the various components. Unless the context clearly dictates otherwise, the singular forms “a,” “an,” or “the” and similar words do not denote a limitation of quantity, but rather denote the presence of at least one. Words like “including” or “comprising” mean that the elements or items listed before “including” or “comprising” cover the elements or items listed after “including” or “comprising” and their equivalents, and do not exclude other component or object. “Up”, “down”, “left”, “right”, etc. are only used to indicate relative positional relationship; and when the absolute position of the described object changes, the relative positional relationship may also change accordingly.

In communication devices, a near-field communication function is mainly realized by a near-field communication antenna. In some communication devices, the near-field communication antenna is formed into a coil structure on a circuit board, and the circuit board provided with the coil structure is attached to a battery or a housing of the communication device. In this arrangement, due to the repeated disassembly and assembly of the battery and the housing, the near-field communication antenna is worn out or inaccurate in alignment, which will affect the propagation of an antenna signal. Moreover, the near-field communication antenna occupies a large space inside the device and cannot meet the design requirements of small electronic products.

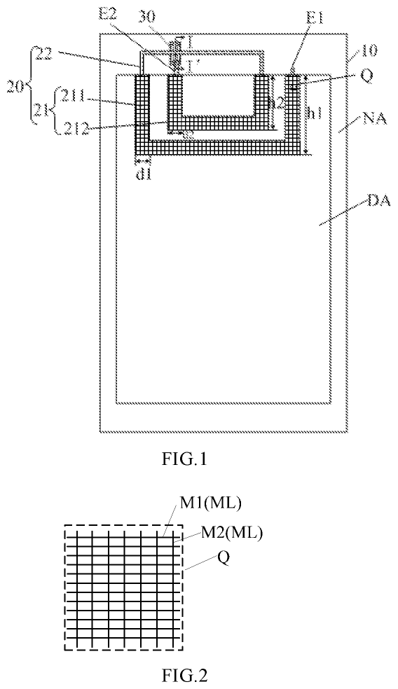

FIG. 1 is a schematic diagram showing a display substrate in some embodiments of the present disclosure. As shown in FIG. 1, the display substrate has a display region DA and a peripheral region NA around the display region DA. The display substrate includes: a base substrate 10 and a display function layer on the base substrate 10. The base substrate 10 may be a glass base substrate 10, or may be made of a flexible organic material, for example resin materials, such as polyimide, polycarbonate, polyacrylate, polyetherimide, polyethersulfone, polyethylene terephthalate, and polyethylene naphthalate. The display function layer may include structures for realizing a display function, such as signal lines, thin film transistors or the like. In addition, a near-field communication antenna 20 is further provided on the base substrate 10. The near-field communication antenna 20 includes a main body 21. The main body 21 is located in the display region DA, and at least a portion of the main body 21 may transmits light. “Transmitting light” refers to having a light transmission rate of 80% and even higher. For example, at least a portion of the main body portion 21 is hollow, or alternatively at least a portion of the main body 21 is made of a light-transmitting material.

The near-field communication antenna 20 is disposed on the display substrate, thereby solving the problem that the near field communication antenna 20 is worn away or inaccurate in alignment, and preventing the propagation of the antenna signal from being affected. In addition, the near-field communication antenna 20 is integrated in the display substrate to improve the integrated level of the equipment, which is favorable to realizing the miniaturization demand of the product. Further, at least a portion of the main body 21 can transmit light, thereby reducing the influence on the display.

FIG. 2 is an enlarged view of a local region Q in FIG. 1. As shown in FIG. 2, in order to prevent the main body 21 from affecting the display effect of the display region DA, in some embodiments of the present disclosure, the main body 21 includes a metal mesh structure. When the main body 21 includes a plurality of bent portions, each of the bent portions includes the metal mesh structure. The metal mesh structure includes a plurality of metal lines ML (e.g., a plurality of first metal lines M1 and a plurality of second metal lines M2). The first metal lines M1 and the second metal lines M2 cross each other to form a mesh shape. For example, the main body 21 may be made of a transparent material such as Indium Tin Oxide (ITO).

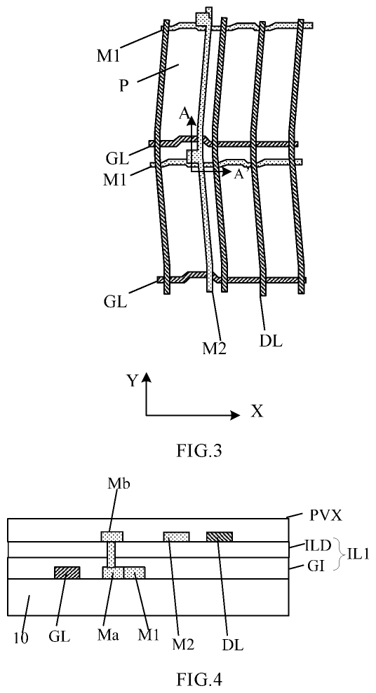

FIG. 3 is a schematic diagram showing wiring in a local region of a display substrate in some embodiments of the present disclosure, and FIG. 4 is a cross-sectional view taken along a line A-A′ in FIG. 3. As shown in FIGS. 3 to 4, a display function layer on the base substrate 10 includes a plurality of signal lines including a plurality of gate lines GL and a plurality of data lines DL. The gate lines GL and the data lines DL cross to each other to define a plurality of pixels P. Each of the pixels is provided with structures such as a thin film transistor, a pixel electrode, and the like. Taking an embodiment in which the display substrate is applied for a liquid crystal display panel as an example, a gate electrode of the thin film transistor is connected to a corresponding gate line GL, a source electrode of the thin film transistor is connected to a corresponding data line DL, and a drain electrode of the thin film transistor is connected to a corresponding pixel electrode. The gate electrode of the thin film transistor and the gate line GL are located in a gate metal layer. The source electrode and the drain electrode of the thin film transistor and the data line DL are located on a source-drain metal layer. A gate insulation layer GI is located between the gate metal layer and an active layer of the thin film transistor. An interlayer dielectric layer ILD is located between the active layer and the source-drain metal layer. A passivation layer PVX is located between the source-drain metal layer and the pixel electrode. The pixel electrode is connected to the drain electrode of the thin film transistor through a through-hole in the passivation layer PVX. In addition, a common electrode, which is a strip electrode and insulated and spaced from the pixel electrode, is formed on the display substrate. After an electric signal is supplied to the common electrode and the pixel electrode, an electric field is generates in a liquid crystal layer of the display panel. Alternatively, the pixel electrode and the common electrode may also be formed in other manners. For example, the common electrode is disposed on a side of the passivation layer PVX away from the base substrate 10, each of the pixel electrode and the drain electrode of the thin film transistor is disposed between the passivation layer PVX and the interlayer dielectric layer ILD. The pixel electrode is directly connected to the drain electrode of the thin film transistor without an insulation layer therebetween.

In some embodiments, at least one of the first metal line M1 and the second metal line M2 is disposed at the same layer as at least one of the signal lines, so as to simplify the manufacturing process.

Optionally, at least one of the first metal line M1 and the second metal line M2 is disposed in the same layer as the gate line GL or the data line. The first metal line M1 and the second metal line M2 are located in different layers that are insulated and spaced apart from each other. The first metal line M1 and the second metal line M2 are connected to each other through a through-hole at a crossing position where the first metal line M1 crosses the second metal line M2.

For example, as shown in FIG. 4, the first metal line M1 of the metal mesh structure is located at the gate metal layer, i.e., the first metal line M1 is disposed on the same layer as the gate line GL; the second metal line M2 is located in the source-drain metal layer, that is, the second metal line M2 is disposed on the same layer as the data line DL. A first insulation layer IL1 (i.e., the gate insulation layer GI and the interlayer dielectric layer ILD) is disposed between the gate metal layer and the source-drain metal layer, and the first metal line M1 and the second metal line M2 are connected to each other through a through-hole in the first insulation layer IL1 at a position where the first metal line M1 and the second metal line M2 intersect with each other. For example, the first metal line M1 and the first connection portion Ma are formed as a one-piece structure, and the second metal line M2 and the second connection portion Mb are formed as a one-piece structure. The first connection portion Ma is connected to the second connection portion Mb through a through-hole in the first insulation layer ILL thereby achieving connection between the first metal line M1 and the second metal line M2.

In the embodiments shown in FIGS. 3 and 4, the main body 21 of the near-field communication antenna 20 in the display region DA does not increase a thickness of the display substrate, which is advantageous for realizing the lightness and thinness of the communication device. In addition, the first metal line M1 may be fabricated in synchronization with the gate line GL, and the second metal line M2 may be fabricated in synchronization with the data line DL, thereby simplifying the manufacturing process and reducing the process cost.

FIG. 5 is a cross-sectional view showing a display panel in some embodiments of the present disclosure, and the cross-sectional line of FIG. 5 is the line A-A′ in FIG. 3. As shown in FIG. 5, in the display panel, a display substrate faces a counter substrate 40, and a black matrix BM for shielding structures such as gate lines GL, data lines DL, and thin film transistors on the display substrate is disposed on the counter substrate 40.

When the first metal line M1 is disposed in the same layer as the gate line GL and the second metal line M2 is disposed in the same layer as the data line DL, the first metal line M1 and the second metal line M2 may be shielded by the black matrix BM by adjusting a width of the black matrix BM. Considering that increasing the width of the black matrix BM may affect the aperture ratio of the pixel P, in the embodiment of the present disclosure, a distance between the first metal line M1 and the gate line GL is set to be 1/7 to ¼ of a pitch between two adjacent gate lines GL, and a distance between the second metal line M2 and the data line DL is set to be 1/7 to ¼ of a pitch between two adjacent data lines DL.

The plurality of pixels P of the display substrate may include a plurality of pixel groups each including m pixels P arranged in an X direction. For example, each of the pixel groups includes three pixels respectively, that is, a red pixel, a green pixel, and a blue pixel. In this case, in order to make the aperture ratios of the pixel groups in the region where the near-field communication antenna 20 is located uniform, it is preferable that one gate line GL is formed between any two adjacent first metal lines M1 arranged in a Y direction, and m data lines DL are formed between any two adjacent second metal lines M2 arranged in the X direction. It should be noted that the red pixel, the green pixel, or the blue pixel mean that the red pixel, the green pixel, or the blue pixel of the display panel emits red light, green light or blue light respectively when a display panel including the display substrate displays. For example, red, green and blue filter layers may be formed on the counter substrate 40.

In some embodiments, an extending direction of the first metal lines M1 is the same as an extending direction of the gate lines GL, and an extending direction of the second metal lines M2 is the same as an extending direction of the data lines DL. In the embodiment of the present disclosure, the two signal lines having the same extending direction means that the two signal lines have substantially the same extending direction and substantially the same shape, so that the two signal lines have the same distance or substantially the same distance therebetween at different positions. For example, both signal lines are straight lines, or alternatively both signal lines are bent with the same bending tendency. For example, as shown in FIG. 3, the gate line GL extends in the x direction substantially but bends at a certain position, and the first metal line M1 extends in the x direction substantially but bends at a certain position. Each of the data line DL includes straight-line portions located between two adjacent gate lines GL, the extending directions of two adjacent straight-line portions of the data line DL are different from each other and each form a certain included angle (e.g., 5° to 15°) with regard to the y direction. The data line DL extends along the y direction substantially. Each of the second metal line M2 includes straight-line portions located between two adjacent gate lines GL, the extending directions of two adjacent straight-line portions of the second metal line M2 are different from each other and each form a certain included angle with regard to the y direction. The second metal line M2 DL extends along the y direction substantially.

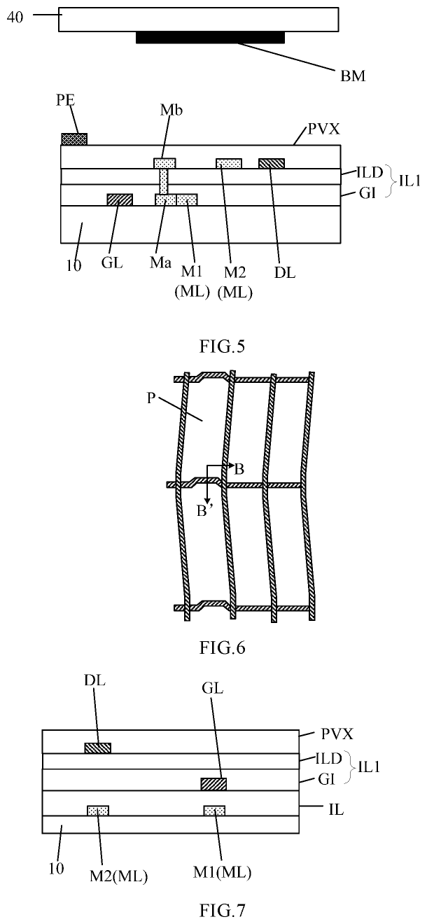

FIG. 6 is a schematic diagram showing a local region of a display substrate other embodiments of the present disclosure, and FIG. 7 is a cross-sectional view taken along a line B-B′ of FIG. 6. As shown in FIGS. 6 to 7, similar to FIG. 3, the display function layer on the base substrate 10 includes a plurality of signal lines such as a plurality of gate lines GL and a plurality of data lines DL which are arranged in the same manner as FIG. 3, and only differences between FIG. 6 and FIG. 3 will be described below.

In FIGS. 6 to 7, an orthographic projection of at least one metal line ML on the base substrate 10 is located within an orthographic projection of a corresponding signal line on the base substrate 10, thereby reducing an influence of the metal line ML on an aperture ratio of the pixel P.

Optionally, an orthographic projection of each of the metal lines ML on the base substrate 10 is located within an orthographic projection of a corresponding signal line on the base substrate 10. For example, an orthographic projection of the first metal line M1 on the base substrate 10 is located within an orthographic projection of a corresponding gate line GL on the base substrate 10, and an orthographic projection of the second metal line M2 on the base substrate 10 is located within an orthographic projection of a corresponding data line DL on the base substrate 10. The first metal line M1 may be located on a side of the gate line GL away from the base substrate 10 or located between the gate line GL and the base substrate 10; the second metal line M2 may be located on a side of the data line DL away from the base substrate 10 or located between the data line DL and the base substrate 10.

In some examples, the first metal line M1 and the second metal line M2 are disposed in the same layer, that is, the first metal line M1 and the second metal line M2 are directly connected to each other at an intersection where the first metal line M1 crosses the second metal line M2, thereby simplifying the process steps and preventing the thickness of the display substrate from being excessively large. In addition, the signal lines such as the gate lines GL and the data lines DL are disposed on a side of the metal mesh structure away from the base substrate 10, and the gate lines GL and the metal mesh structure are spaced apart from each other by the insulation layer IL, so that an influence of transmitting and receiving signals by the near-field communication antenna 20 on a display process of the display substrate can be reduced.

As shown in FIG. 1, the near-field communication antenna 20 further includes: a connection line 22 in the peripheral region NA. The connection line 22 and the main body 21 are connected to each other and then form a coil of the antenna 20. Both terminals of the coil of the antenna 20 are connected to a control circuit. Specifically, as shown in FIG. 1, the main body 21 includes a plurality of bent portions 211 and 212 (e.g., U-shaped structures in FIG. 1), and the terminals of the plurality of bent portions 211 to 212 are sequentially connected to each other through the connection line 22 to form a loop-shaped coil of the antenna. That is, a first terminal of the bent portion 211 serves as a first terminal of the antenna coil, a second terminal of the bent portion 211 is connected to a first terminal of the bent portion 212, and a second terminal of bent portion 212 serves as a second terminal of the antenna coil. The near-field communication antenna 20 further includes a first leading-out terminal E1 and a second leading-out terminal E2. The first leading-out terminal E1 and second leading-out terminal E2 are connected to the first and second terminals of the antenna coil, respectively. A bridge 30 is further formed in the peripheral region NA. One terminal of the bridge 30 is connected to to the second leading-out terminal E2, and the other terminal of the bridge 30 is connected to a control circuit. When near-field communication is performed, the near-field communication antenna 20 and the control circuit form a closed loop, and an induced current loop can be formed in the near-field communication antenna 20 and the control circuit through an external magnetic induction coil, so that near-field communication is realized.

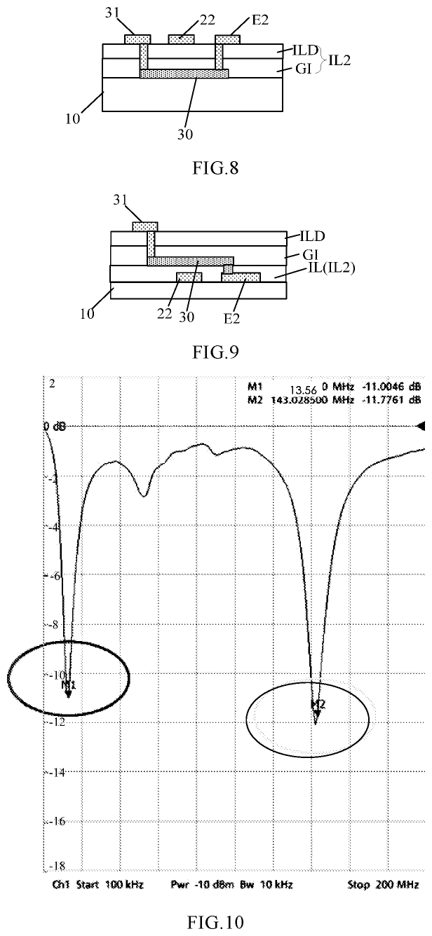

FIG. 8 is a cross-sectional view taken along a line I-I′ of FIG. 1 in some embodiments of the present disclosure. When the first metal line M1 of the metal mesh structure is disposed in the same layer as the gate line GL and the second metal line M2 is disposed in the same layer as the data line DL, the cross-sectional view taken along a line I-I of FIG. 1 is as shown in FIG. 8, the first leading-out terminal E1, the second leading-out terminal E2 and the connection line 22 are disposed in the same layer, that is, in the source-drain metal layer. The first leading-out terminal E1 and the second leading-out terminal E2 are connected to the plurality of second metal lines M2 of the metal mesh structure. An orthographic projection of the connection line 22 on the base substrate passes through or crosses an orthographic projection of the bridge 30 on the base substrate 10. A second insulation layer IL2 is located between a layer where the bridge 30 is formed and a layer where the connection line 22 is formed. In some examples, the bridge 30 is located in the gate metal layer, and at this time the second insulation layer IL2 and the first insulation layer IL1 are the same layer. The second leading-out terminal E2 is connected to one terminal of the bridge 30 through a through-hole in the second insulation layer IL2, and the other terminal of the bridge 30 is connected to the control circuit. For example, the peripheral region NA is formed therein with a binding terminal 31 connected to the control circuit, the binding terminal 31 is located in the source-drain metal layer, and the binding terminal 31 is connected to the other terminal of the bridge 30 through a through-hole in the second insulation layer IL2, so that the other terminal of the bridge 30 is connected to the control circuit through the binding terminal 31.

FIG. 9 is a cross-sectional view taken along a line I-I′ of FIG. 1 according to other embodiments of the present disclosure. When the first metal line M1 and the second metal line M2 of the metal mesh structure are disposed in the same layer, the cross-sectional view taken along a line I-I′ of FIG. 1 is as shown in FIG. 9, the first leading-out terminal E1, the second leading-out terminal E2 and the connection line 22 are all disposed in the same layer as the metal mesh structure, and the first leading-out terminal E1 and the second leading-out terminal E2 are all directly connected to the metal mesh structure. A second insulation layer IL2 is formed between a layer where the bridge 30 is located and a layer where the connection line 22 is located. In some examples, the bridge 30 is located in the gate metal layer, in this case, the second insulation layer IL2 and the insulation layer IL are the same layer. One terminal of the bridge 30 is connected to the second leading-out terminal E2 through a through-hole in the second insulation layer IL2, and the other terminal of the bridge 30 is connected to the control circuit. For example, the peripheral region NA is formed therein with a binding terminal 31 connected to the control circuit, the binding terminal 31 is located in the source-drain metal layer, and the binding terminal 31 is connected to the other terminal of the bridge 30 through a through-hole penetrating through the interlayer dielectric layer ILD and the gate insulation layer GI, so that the other terminal of the bridge 30 is connected to the control circuit through the binding terminal 31.

In some embodiments, the peripheral region NA includes a first sub-region and a second sub-region respectively located at two opposite sides of the display region DA. Pads are formed in the first sub-region, and the pads are connected to a driving circuit board for providing display driving signals for the display substrate. The connection line 22 and the bridge 30 are located in the second sub-region.

It should be noted that the display substrate in the embodiments of the present disclosure may be applied to liquid crystal display panels, and may also be applied to OLED (i.e., Organic Light-Emitting Diode) display panels. In above embodiments in which the display substrate is applied to the liquid crystal display panels, the arrangement manner of the metal mesh structure is illustrated. When the display substrate is applied to the OLED display panels, a pixel circuit and a light emitting device connected to the pixel circuit may be formed in a pixel, the pixel circuit includes a plurality of transistors, and the signal lines on the display substrate may further include power lines, reset lines, light-emitting control lines, and the like. In this case, when the first metal line M1 and the second metal line M2 of the metal mesh structure are in the same layer, an orthographic projection of the first metal line M1 on the base substrate 10 may be located within an orthographic projection of a corresponding gate line GL on the base substrate 10, or within an orthographic projection of another corresponding signal line (e.g., the reset line or the light-emitting control line) on the base substrate 10. An orthographic projection of the second metal line M2 on the base substrate 10 may be located within an orthographic projection of a corresponding data line DL on the base substrate 10, or within an orthographic projection of another corresponding signal line (e.g., the power supply line) on the base substrate 10.

An embodiment of the present disclosure further provides a display panel. As shown in FIG. 5, the display panel includes above display substrate. In addition, the display panel further includes a counter substrate 40 and a black matrix BM on the counter substrate 40. All of orthographic projections of the gate lines GL, the data lines DL and the metal lines ML of the metal mesh structure on the base substrate 10 are located within an orthographic projection of the black matrix on the base substrate 10.

An embodiment of the present disclosure further provides a display device, which includes above display panel and a control circuit. The control circuit is connected to the near-field communication antenna 20.

The display device can be a product or a device with a display function and a communication function, such as a liquid crystal display panel, an OLED panel, a mobile phone, a tablet computer, a digital photo frame, a navigator and the like.

In some examples, the control circuit is formed in the periphery region on the base substrate. In other examples, the control circuit is disposed on a circuit board connected to the display substrate, such that the control circuit is connected to the near-field communication antenna through a connection terminal on the circuit board and a connection terminal on the display substrate.

FIG. 10 is diagram showing matching of resonance points of the near-field communication antenna in the embodiment of the present disclosure. As shown in FIG. 10, the near-field communication antenna 20 has the best communication effect near a point M1 with a frequency about 13.56 MHz and the S11 parameter value about −11 dB. Therefore, in applications, the communication distance of the antenna 20 can be adjusted by adjusting the number of turns of the antenna 20.

Table 1 shows simulation data and actual measurement data for the near-field communication antenna in the embodiments of the present disclosure. The near-field communication antenna includes two turns of coil, that is, the main body 21 includes two bending portions 211 and 212 in FIG. 1. The bent portion 211 has a height h1 of 57 mm and a width d1 of 38 mm; the bent portion 212 has a height h2 of 38 mm and a width d2 of 38 mm. In actual measurements, five near-field communication antennas are tested, and measurements of the different near-field communication antennas slightly differ due to the manufacturing process and measurement accuracy. However, as shown in table 1, in five measurements, the communication distance measured each time is greater than 5 cm, which satisfies the requirements in practical application.

TABLE 1

| Specification | | Actually Measured | | | | |
|---|---|---|---|---|---|---|
| Parameters | Simulation | First | Second | Third | Fourth | Fifth |
| Resistance (Ω) | 9 | 40.2 | 39.9 | 40.1 | 40.5 | 39.8 |
| Inductance (μH) | 0.3 | 0.015 | 0.013 | 0.014 | 0.014 | 0.016 |
| Self Resonant | 139 | 117 | 115 | 117 | 118 | 120 |
| Frequency | | | | | | |
| (Hz) | | | | | | |
| Communication | 4.0 | 5.2 | 5.1 | 5.1 | 5.1 | 5.1 |
| Distance (cm) | | | | | | |

It should be understood that the above embodiments are merely exemplary embodiments adopted to explain the principles of the present disclosure, and the present disclosure is not limited thereto. It will be apparent to one of ordinary skill in the art that various changes and modifications may be made therein without departing from the spirit and scope of the present disclosure, and such changes and modifications also fall within the scope of the present disclosure.

1. A display substrate having a display region and a non-display region, wherein the display substrate comprises:
a base substrate; and
a near-field communication antenna on the base substrate and comprising a main body,
wherein the main body is in the display region, and at least a portion of the main body is transparent.

2. The display substrate of claim 1, wherein the body portion comprises a metal mesh structure.

3. The display substrate of claim 2, further comprising a plurality of signal lines on the base substrate,
wherein the plurality of signal lines are in the display region and insulated and spaced apart from the near-field communication antenna, and
the metal mesh structure comprises a first metal line and a second metal line intersected with each other.

4. The display substrate of claim 3, wherein the plurality of signal lines comprises a plurality of gate lines in a gate metal layer and a plurality of data lines in a source-drain metal layer, and an orthographic projection of the plurality of gate lines on base substrate and an orthographic projection of the plurality of data lines on base substrate intersect with each other, and the plurality of gate lines and the plurality of data lines are spaced apart from each other by a first insulation layer, and the first metal line and the second metal line are connected to each other through a through-hole at a position where the first metal line intersects with the second metal line, and at least one of the first metal line and the second metal line is in the same layer as the plurality of gate lines or the plurality of data lines.

5. The display substrate of claim 2, further comprising a plurality of signal lines on the base substrate, the plurality of signal lines being in the display region and insulated and spaced apart from the near-field communication antenna,
wherein the metal mesh structure comprises a plurality of metal lines, and an orthographic projection of at least one of the plurality of metal lines on the base substrate is within an orthographic projection of a corresponding signal line on the base substrate.

6. The display substrate of claim 5, wherein an orthographic projection of each of the plurality of metal lines on the base substrate is within an orthographic projection of a corresponding signal line on the base substrate.

7. The display substrate of claim 6, wherein the metal mesh structure comprise a plurality of first metal lines and a plurality of second metal lines intersected with each other,
the plurality of signal lines comprise a plurality of gate lines and a plurality of data lines intersected with each other and insulated and spaced apart from each other, and
an orthographic projection of each of the plurality of first metal lines on the base substrate is within an orthographic projection of a corresponding gate line on the base substrate, and an orthographic projection of each of the plurality of second metal lines on the base substrate is within an orthographic projection of a corresponding data line on the base substrate.

8. The display substrate of claim 7, wherein the plurality of first metal lines and the plurality of second metal lines are in a same layer, and the plurality of signal lines are on a side of the metal mesh structure away from the base substrate.

9. The display substrate of claim 1, wherein the near-field communication antenna further comprises: a connection line in the non-display region, wherein the connection line and the main body are connected to each other to form an antenna coil, and two terminals of the antenna coil are connected to a control circuit.

10. The display substrate of claim 9, wherein the near-field communication antenna further comprises: a first leading-out terminal and a second leading-out terminal respectively connected to first and second terminals of the antenna coil, wherein the first leading-out terminal, the second leading-out terminal and the connection line are in a same layer, and
the non-display region is further formed with a bridge therein, an orthographic projection of the connection line on the base substrate intersects with an orthographic projection of the bridge on the base substrate, a second insulation layer is between a layer where the bridge is located and a layer where the connection line is located, the second leading-out terminal is connected to one terminal of the bridge through a through-hole in the second insulation layer, and the other terminal of the bridge is connected to the control circuit.

11. A display panel comprising the display substrate of claim 1.

12. The display panel of claim 11, wherein the main body comprises a metal mesh structure, the display panel further comprises a counter substrate and a black matrix on the counter substrate, and an orthographic projection of metal lines of the metal mesh structure on the base substrate is within an orthographic projection of the black matrix on the base substrate.

13. A display device comprising the display panel of claim 11 and a control circuit connected to the near-field communication antenna.

14. A display device comprising the display panel of claim 12 and a control circuit connected to the near-field communication antenna.

15. A display panel comprising the display substrate of claim 2.

16. A display panel comprising the display substrate of claim 3.

17. A display panel comprising the display substrate of claim 4.

18. A display panel comprising the display substrate of claim 5.

19. A display panel comprising the display substrate of claim 6.

20. A display panel comprising the display substrate of claim 7.
